(19) United States
(12) Patent Application Publication
(10) Pub. No.: US 2018/0269828 A1
(43) Pub. Date: Sep. 20, 2018

(54) DEVICE FOR GENERATING ELECTRICAL ENERGY

(71) Applicant: DUROPAN ALLIANCE GMBH, Halberstadt (DE)

(72) Inventor: Wolfgang Beck, Blankenburg (DE)

(21) Appl. No.: 15/735,240

(22) PCT Filed: Jun. 9, 2016
(86) PCT No.: PCT/EP2016/063119

§ 371 Date: Jun. 4, 2018

(30) Foreign Application Priority Data
Jun. 9, 2015 (DE) 10 2015 007 236.6

(51) Int. Cl. H02S 40/44; H02S 40/42; H01L 35/32; H05K 1/02; C09J 9/02; C09J 11/04; C09J 11/06

(52) U.S. Cl. CPC H02S 40/44; H02S 40/425; H01L 35/32; H05K 1/0272; H05K 2201/10219; C09J 9/02; C09J 11/04; C09J 11/06; H05K 2201/10143; H05K 1/0203

(57) ABSTRACT

The present invention relates to a device for generating electrical energy, comprising a photovoltaic cell (PV) which is connected to a carrier plate (BA) through which fluid can flow in a heat-conducting manner.

The invention relates to a device for generating electrical energy, that is to say a hybrid system of at least one thermal transmitter, for example a thermophotovoltaic system (TPV), and combines thermovoltaic technology with photovoltaic technology, in particular in an integrally bonded manner, and consists of a thermal transmitter, which for example by means of at least one carrier plate as thermal diffuser, through which fluid flows, and at least one thermal barrier, is connected to at least one embedded thermoelectric generator and to at least one thermal accumulator and to at least one photovoltaic system, which in particular is positioned in an integrally bonded and/or heat-transmitting manner.

### PRIOR ART

In photovoltaic technology, the performance losses are dependent on the module heat. For example, in the summer months the module is heated to approximately (80-90) degrees Celsius, and this can rise to 130 degrees Celsius depending on the design and environment. In the case of a 200 watt solar power module, this leads for example to the generation of 135 watts at 90 degrees Celsius (approximately 32)% performance loss and at 125 degrees Celsius to the generation of 100 watts (approximately 50)% performance loss.

In the prior art the problem of thermal overheating is solved in different ways. In DE 20 2012 002 836 U1 the cooling is performed by means of a water sprinkler system. In DE 10 2008 027 000 A1 the cooling is achieved by means of a heat-dissipating plastics material on the module rear side. DE 2009 003 904 U1 proposes a cooling system which is controlled in a decentralised manner and which dissipates the heat sequentially.

DE 20 2010 017 772 U1 describes a process for producing a circuit board with cooling fluid channel. In DE 10 2007 055 937 A1 a thermal transmitter is described for direct conversion of heat energy into electrical energy. The transmitter has a plastics material surface suitable for the adsorption of heat energy, in particular infrared radiation. The thermal transmitter has a layered structure with a thermal accumulator, a thermal transmitter, followed by a thermal diffuser and a cold source. The thermal accumulator consists of a polymer matrix doped with semiconductor particles and ensures the function of the thermal coupler and thermal conductor. The thermal coupling within the polymer matrix is provided by means of IR-absorbing pigments (n- or p-conducting and/or doped) and/or similar nanoscale, crystalline materials, which enable a strong adsorption of infrared radiation in the wavelength range of from 800 nm to 1500 nm. The thermal conductor has the task of ensuring the thermal conduction within the polymer matrix and is produced by means of carbon nanotubes (CNTs), carbon nanohorns (CNCs), or carbon nanofibres.

The thermal diffuser is used here in order to produce the temperature gradient.

The term “thermophotovoltaic cells” is understood to mean cells based on InP or GaSb, which do not utilise sunlight, but instead use thermal radiation, i.e. light of a much higher wavelength. Efficiency has been increased here to (9-12)%.

### Disadvantages of the Prior Art

A feature common to all systems is that the heat is discharged with different effect, and the accumulated heat energy is lost without further electrical usage, or with only low further electrical usage. A further disadvantage of all the solutions is the need for additional plant equipment and/or industrial equipment for the application and operation of additional cooling devices. Furthermore, the low efficiency, in particular of Peltier and Seebeck elements, is caused by the undesirable conduction of heat between the metals or semiconductors. All of these disadvantages are compensated for in the thermophotovoltaic system by a new technical solution.

The object of the present invention is to specify a method for a thermophotovoltaic system and a device having improved efficiency. This object is achieved by a device according to claim 1 and by particular embodiments in the dependent claims. Further details, features and advantages of the subject matter of the invention will become clear from the dependent claims and from the description and drawings.

This object is achieved with the present invention by a device having the features of claim 1. This device has a photovoltaic cell, known per se, which is connected heat-conductively to a carrier plate through which fluid can flow. The solar energy conducted through the photovoltaic cell can be dissipated by means of convection via the carrier plate through which fluid can flow. Here, the flow channels within the carrier plate can be used solely for cooling. The heat thus obtained and stored in the fluid can likewise be used to generate energy.

To this end, at least one thermoelectric generator is provided, preferably as part of the carrier plate through which fluid can flow, which generator is thermally coupled to a flow channel of the carrier plate. A thermoelectric generator of this kind can be formed for example by a Peltier element, which generates a current on account of a temperature difference. Here, one side of the Peltier element is thermally coupled to the photovoltaic cell and the other to a flow channel of the carrier plate, so that the thermoelectric generator lies between a cold side and a warm side. Here, the photovoltaic cell preferably forms the “warm side”. The carrier plate is preferably formed as a circuit board with electric conductor tracks, wherein the electric conductor tracks are electrically conductively connected to the thermoelectric generator(s). Here, the circuit board usually carries the thermoelectric generator(s) on its surface.

In accordance with a preferred embodiment of the present invention, the photovoltaic cell is formed as part of a unitary circuit board. The corresponding cell is thus connected together with the electric circuit board to form a unit. This circuit board forms the conductor tracks for the photovoltaic cell and also the conductor tracks to the thermoelectric generator. Furthermore, the recess or recesses forming the flow channels or flow channels is/are formed in the circuit board.

In accordance with a further preferred embodiment of the present invention, an inlay is embedded in the carrier plate. This inlay is formed from a material that is a good conductor of heat. The inlay is usually made of metal, but in any case preferably of a material that has a thermal conductivity of at least 300 W/(m K). This inlay incorporated in the carrier plate extends between the thermoelectric generator and the flow channel, or the thermoelectric generator and the photovoltaic cell, in order to feed the temperatures prevailing at the hot or cold side of the thermoelectric generator to the thermoelectric generator in the best possible way.

The adhesive preferably used in order to produce the adhesive bond in the device according to the invention is defined in claim 13. The specified percentages of component B relate to amounts in percent by weight. Insofar as component B contains auxiliaries, these can be nonspecific substances which do not enter into any chemical interaction with the other constituents of component B and/or component A in the sense of modifying the adhesive bond. Auxiliaries can thus be fillers which are dispersed in the adhesive, or impurities. Auxiliaries are in particular stabilisers, aeration reducers, and anti-foaming agents.

Further preferred embodiments of the device according to the invention are described in the dependent claims.

### DISCLOSURE OF THE INVENTION

The underlying concept of the invention is that the thermophotovoltaic system is based on a circuit board through which fluid flows. The underlying concept of the invention is that the device for generating electrical energy, also referred to hereinafter as a “thermophotovoltaic system”, comprises a carrier plate through which fluid flows. This carrier plate can also be a circuit board with conductor tracks held therein that are electrically insulated from one another, said circuit board also being known as a PCB (printed circuit board), wherein this circuit board usually contains at least one flow channel, preferably a plurality of flow channels in the form of a capillary network system. This capillary network system can be formed in accordance with the Tichelmann principle.

This circuit board, also referred to as a PCB (printed circuit board), includes a capillary network system for forming the flow channels, by way of example in accordance with the Tichelmann principle. The capillary network system is in particular arranged within the circuit board, in particular beneath what is known as the copper inlay for the thermoelectric generators. The inlays form the bond, in particular the material surface for direct contact with the thermoelectric generator level; this being provided alternatively and in particular also directly for silicon-based photovoltaic (PV) cells (PV solar cells). The thermoelectric generator level is also referred to here as a thermal barrier, because it separates the hot side from the cold side of the thermoelectric generator level and thus ensures that the heat flows exclusively through the generators. Here, in particular the gaps formed during the assembly of the generators are connected, in particular potted, using a thermally non-conductive material, in particular plastics material and/or resin. The solution is based in particular on at least one thermal transmitter. The terms “bond”, “connected”, and “connect” are understood here in particular to mean a joining in accordance with the physical principles of action, in an integrally bonded, positively engaged, or frictionally engaged manner, and combinations thereof.

The hybrid system of the thermal transmitter, for example the thermophotovoltaic system (TPV), combines thermovoltaic technology and photovoltaic technology in an integrally bonded manner and consists of a thermal transmitter, for example at least one carrier plate through which fluid flows as thermal diffuser, at least one thermal barrier with at least one embedded thermoelectric generator, and at least one thermal accumulator and at least one photovoltaic system positioned in an integrally bonded and/or heat-transmitting manner.

The application system consists of at least one circuit board through which fluid flows, which board is equipped internally with structured capillaries, in particular in accordance with the Tichelmann principle, inclusive of associated fluid connection elements. The capillaries have geometric structures, in particular in the form of structures having at least a T-shape and/or at least an H-shape and/or at least a Y-shape and/or a loop; and/or in particular at least part of the surfaces, in particular (60 to 90)% of the inner side of the capillary has a structural surface, in particular by means of roughness, and/or in particular at least part of the cross-sectional shape of the capillary, in particular (60 to 90)% of the capillary, in particular has a geometric rhombus shape.

The Tichelmann principle and the functionality lie in particular in the fact that the fluid flowing through, in particular water or the coolant and/or heat carrier has the same path everywhere, in particular has to travel over the same line length. Here, the lengths of the supply and return lines are considered jointly, and technically the same pressure losses occur for each consumer, so that the mass flow is advantageously distributed uniformly. Here, it must be taken into consideration that the outputs or resistances in all modules are approximately the same, in particular with a potential tolerance of (10 to 20)%. There is also the further advantage that a simple possibility exists to hydraulically balance a system. Based on the same arrangement of supply and return lines, in particular capillaries, the system is easy to construct and operate and requires no additional technical control means and also has no moving parts, which could lead to defects or malfunctions. This increases the operating reliability of the plant advantageously.

The application system, consisting by way of example of at least one circuit board through which fluid flows and which is equipped with and connected to inlays for the assembly of the component parts, thus ensures an optimal transfer of heat to the capillary system of the circuit board. In a further particular embodiment, a reduction of the internal friction in the capillaries inter alia is also possible, in particular by means of fluid and/or material pairings and/or a special inner surface structure, in particular a surface having functionality based on shark's skin. Material pairings in particular can be pairings that have a high thermoelectric force, for example by means of silicides, tellurides, and also skutterudites.

The surface having a functionality based on shark's skin is provided in particular by means of nanoparticles on the surface and/or laser processing, in particular so as to form recesses on the surface and/or to reduce the roughness, for example for smoothing, and/or to increase roughness. The surface can also be microstructured by means of laser and/or etching and/or electron beam blasting, which results in further rises in thermoelectric efficiency.

The nanoparticles, in particular an accumulation of nanoparticles, are arranged for example on a base plate and/or circuit board approximately (1-3) mm thick, wherein the nanoparticles sit very closely together, overlap and/or engage with one another in part, and depending on their type are in particular (200-500) nm large and by way of example and advantageously each have their own surface relief. Further particular dimensions with the functionality based on shark's skin are: riblet height: (56-96) μm, riblet spacing: (67-97) μm, angle: a approximately (53-73°); riblet width: (66-86) μm, channel width at the base: (8-15) μm. There is also an improvement in the resistance reduction, even in the case of a surface of limited functionality, in particular if the surface has only approximately (60 to 75)% functionality.

The surface is in particular an area, wherein it is understood to mean the extent of an area in the mathematical sense and/or the delimitation of a three-dimensional geometric body and/or as an interface in the sense of physics and a phase interface in the sense of chemistry, in particular also as an inner surface, for example within a line.

The term “fluid” or “fluids” can also be understood to mean gases, gas mixtures, gas mixtures with particles, in particular nanoparticles, in particular also water with a thermal conductivity of approximately 0.5562 W/(m K) at 0.0° C. (Celsius), but also advantageously in particular ice with a thermal conductivity of approximately 2.33 W/(m K) at −20.0° C., advantageously carbon, in particular graphite, with a thermal conductivity of approximately (110-170) W/(m K) at 20.0° C., advantageously silicon with a thermal conductivity of approximately 148 W/(m K) at 20.0° C., and carbon nanotubes (CNTs) with a thermal conductivity of approximately 6000 W/(m K) at 20.0° C.

A fluid is also understood in particular to mean a liquid, in particular water (hydrojig machine), but also a gas, in particular air. Air is also understood to mean a mixture, in particular of further liquid and/or gaseous and/or other material nature, in particular particles. In particular the air shall have the advantageous effect of thermal conductivity and/or electrically insulating and/or electrically conductive properties. Furthermore, particles, in particular nanoparticles, can be added to and/or mixed with the air, wherein the particle proportion is less than 30% relative to the volume of the gas, in particular between (5 and 15)% or between (60 to 70)%, with the advantageous effect of thermal conductivity and/or electrically insulating and/or electrically conductive properties. Fluids can be compacted and/or compressed and/or decompressed and thus advantageously experience changes in their functional properties, in particular for gaseous, compacted fluid and/or fluid with particles, in particular nanoparticles, for generation of cold and/or heat by means of at least one vortex tube, or for generation of pulsating fluid by means of at least one piezoelement.

A further improvement in the heat transport and/or thermal transfer in the system can be achieved by means of the inner forces of the fluid held together by adhesion and cohesion, for example with a further possibility for control of the heat transport and the thermal transfer in the system being provided in particular by means of nanoparticles, in particular by means of a proportion of less than 10%, in particular less than 40%, of boron nitride (BN) and/or aluminium nitrite (AlN) and/or aluminium oxide (Al2O3), with the particular advantage of good thermal conductivity, in particular a maximum flow of heat through the generator.

In order to be able to adapt the material, in particular the fluid, which also serves as a cold energy carrier and/or heat energy carrier, to the circuit board, a specific and also inventive connection element of variable size, also referred to as a PCB fitting, has been developed, for example for a ⅛″ fitting. The PCB fitting advantageously ensures that the fluid can flow into the circuit board and also out again homogeneously and/or at the same pressure and/or temperature-controlled, in particular cooled. The radius of curvature (R) is considered to be a particular advantage, this being produced by the drilling of the PCB fitting, for example from 3 to 3.2 mm (SW 17 screw, bottom), and in particular together with the fluid comprising nanoparticles enables a particularly homogeneous inflow of the fluid, wherein the size and/or shape of the curvature of radius (R) determines the control, in particular of the swirling of the fluid and/or flow resistance of the fluid. In particular, at least one tapering and/or peripheral tapering, in particular at least one ring, are/is additionally formed on the PCB fitting (SW17 nut, top) in opposition to the flow, and in particular can also act as a convection brake, in particular as a thermosiphon, for example integrated into the horizontal tube at the connection.

In a further particular application, it is advantageous that at least one swirling element is also comprised and/or in particular used in a controlled manner at the connection element, with the advantage that for example in the case of smooth and/or extremely smooth walls of the capillaries, for example with at least a galvanic coating, in particular made of gold, nickel, etc., the laminar flow is disturbed and the heat (energy) exchange relative to the inlays is improved.

A circuit board, also printed board, board or printed circuit (printed circuit board, PCB) is also understood to mean a carrier and/or carrier plate for component parts, in particular electronic and/or thermal component parts. It is used for and/or has the function of a mechanical fastening and/or electrical connection and/or thermal connection and/or thermal transport. In particular in Cordwood circuit technology, at least one electronic and/or at least one thermal component and/or at least one connection, in particular having electrical and/or thermal functionality, is disposed in particular between at least a first and/or a second circuit board, in particular with at least one adhesive (KL). In a further application, circuit boards can improve the thermal management (thermal vias), in particular by the thermal transport perpendicularly to the circuit board and/or transversely to the circuit board and/or beneath the circuit board and/or on the circuit board and/or through the interior of the circuit board, in particular by means of the adhesive (KL). Furthermore, the printed circuit board (B) can also be a module, in particular at least a solar module and/or at least a thermoelectric generator module, in particular formed of at least one semiconductor, in particular a doped semiconductor, (n- and/or p-doped) and/or a further material, in particular copper and/or plastics material and/or resin composite and/or a fibre composite. A circuit board is also understood to mean a circuit board cooled and/or heated by means of fluid, in particular wherein the circuit boards have a modal functionality, in particular as a PV and/or TPV module. In another application, circuit boards cooled by means of at least one fluid are provided, in particular in which the individual layers are connected in particular by means of at least one adhesive (KL) prior to assembly and at least one groove, in particular fine grooves, is/are milled and/or etched and/or formed by means of laser and/or plasma and/or 3D printing on the upper side and underside of the inner layers of the circuit board, and a channel remains after the assembly, in particular in the case of at least one adhesive (KL), through which channel a fluid is conducted. In a particular application at least a first fluid and at least a second fluid can be guided by means of channels closed off for the individual fluid, in particular capillaries (KAP), with the advantage of optimising the functionality, depending on the fluid, and thus achieving an optimum, in particular for the functionality for the transport and/or latent storage of cold and/or heat.

In a further particular application, the circuit board can be produced by means of 3D printing technology in that at least one layer is produced by means of at least a 3D printing of at least one channel, for transporting a fluid, for at least one capillary (KAP), in particular is produced in layers. Furthermore, a thin and/or electrically conductive and/or thermally conductive layer, in particular a copper layer and/or nanoparticle layer and/or electrically and/or thermally conductive layer in which nanoparticles are contained is provided in particular at the narrow sides, which layer is used for improved heating and/or cooling and/or advantageously contributes to a reduced radiation of electromagnetic fields, in particular to electromagnetic compatibility (EMV), and can be used to provide an electrical shielding function, in particular in order to interrupt and/or close a connection to electrical ground, for example so as to avoid galvanic or impedance coupling. Here, in a particular embodiment, the circuit board can be configured in rib form, in particular as a cooling rib and/or a rib tapering conically and/or tapering to a point, in particular with an angle of 3 to 15 degrees and/or truncated in a ratio of baseplate to tip of (1 to 0.8) with (+/−30)% or 1 to (0.7 to 0.9) with (+/−30)% with a length of ratio 1, with the advantage of an improved delivery of the heat.

For example, the following can be used as circuit board base materials: polyimide, Teflon (PTFE), ceramic, in particular aluminium oxide, in particular for reinforcement and/or for the matrix, in particular for improvement of the mechanical and/or thermal and/or electrical properties, embedded by means of at least one material, in particular by means of nanoparticles in a proportion of less than 40%. Furthermore, circuit boards can consist of laminate, and in particular these comprise resin and at least one woven fabric, in particular fibreglass fibres and/or nanofibres in a proportion of less than 40% and/or nanoparticles in a proportion of less than 5%.

Further methods for producing a circuit board include, but are not limited to, casting, foaming, sintering and particularly advantageously moulding methods, such as thixomoulding and combinations thereof. In a further particular embodiment, it is possible that the system comprises at least one ceramic plate as carrier element. The conductor tracks and further channels, in particular but not exclusively the channels for the fluid, can be produced by means of screen printing and/or evaporation. All of these measures can lead to an increase in the efficiency of the system as a whole.

The circuit board can also be a laminate, in particular can be formed by means of at least one laminate, in particular formed from resin and a carrier, in particular woven fabric, nanofibre material and/or nanoparticles. Further possibilities are in particular casting and/or foaming and/or sintering and/or moulding methods, in particular thixomoulding. It is also possible to use a ceramic plate as a circuit board, in particular as a carrier element, in particular by means of 3D printing, wherein in particular conductor tracks and/or paths are applied in particular by means of screen printing and/or by means of evaporation. Here, “conductor paths” is also understood here to mean at least one thermal line and/or at least one thermal material and/or at least one electrical line and/or a static reinforcement.

In a particular application, the carrier plate is constructed entirely taking the thinnest layers possible into consideration. Taking the problems regarding the layers and interfaces into consideration, at least one metal layer and/or adhesive layer and/or top layer of less than 40 μm, in particular with a thickness of at least one layer and/or at least one functional layer of from 0.001 μm to 0.1 μm and/or 0.2 μm to 20 μm, are/is characteristic of the system and have/has an advantage and decisive influence on the system as a whole.

In a particular application, the PCB fitting can be formed such that at least one vortex tube functionality for deliberate and/or controlled cooling and/or heating is in particular integrated and/or contained in at least one PCB fitting, in such a way that in particular it is provided as an additional module and/or in an integrated manner on the limb as an extension of the PCB fitting (SW17). Here, the hot exit stream of the vortex tube can advantageously be fed into the required fluid channel used for heat, in particular at the PV module for advantageous temperature control, and can be fed at the cold end of the vortex tube into the required fluid channel used for cold, in particular at the TPV module.

The term “metal” or “metals” is furthermore also understood to mean semi-precious metals, alloys, for example bismuth, constantan, nickel, platinum, carbon, and also nanocarbon, such as carbon nanotubes (CNTs), nanohorns, aluminium, rhodium, copper, gold, silver, iron, Ni-chromium, and also Bi2Te3, lead telluride PbTe, SiGe, BiSb or FeSi2.

The advantage of the thermal transmitter is the technology for direct conversion of heat energy into electrical energy, for example by the production of a thermal accumulator, for example with at least one plastics material surface, which has an extremely high absorption capability for heat energy, for example in the heat and infrared wave range.

A further advantage is the direct conversion of heat into electrical energy without any mechanical components. Further advantages of the invention and/or of the method according to the invention are the ecological nature on account of emission-free technology for multiple utilisation of heat energy, and also sustainability on account of the use of the thermal potentials widely available worldwide. Another advantage is that the direct and best-possible coupling of the heat to the thermoelectric generators is of decisive importance. The plastics material and/or adhesive thus perform/performs an important function with regard to the elimination of air from the system, in particular during manufacture. In a particular application, the plastics material can also be the adhesive, in particular in the form of a latent thermal store. A further advantage of this system is that the nanoparticles penetrate into the smallest cavities and displace the air contained therein. In a further particular application, it is advantageous in particular for a possible reduction of the air from the system, in particular down to zero percent, to perform the manufacture in particular by means of plastics material, in particular by means of the adhesive and/or with addition by means of nanoparticles of approximately (3 to 30)% (+/−30)% and/or further materials. These advantageously penetrate into the smallest cavities and displace the materials contained therein, in particular air and/or fluids, in particular in the case of ceramic and/or in particular with a roughness profile of approximately (10 to 20) μm.

### Overview of the Invention

The thermal actuator is the core element in the described thermal transmitter and by comparison takes on the function of heat collector and/or also collector of a conventional solar plant. What is novel and advantageous is the use of semiconductive material, in particular pigments, in particular carbon nanotubes and/or nanoparticles, in particular formed from semi-precious metals and/or ceramic substances in a plastics material and/or ceramic and/or circuit board.

The thermoelectric generators are produced for example in at least a two-component system, in particular by means of 3D printing, and are connected, in particular in an integrally bonded manner, in particular adhesively bonded, which for example is extremely thermally conductive. With the same system, in particular the silicon-based solar plant for generating power or also photovoltaic plant (PV solar cells for short) is/are applied in an integrally bonded manner to the hot side of the generators. The two-component system, consisting for example of a heat-conducting material, in particular plastics material, also serves as a thermal accumulator and/or thermal adhesive. The thermal accumulator consists in particular of a doped polymer matrix, which is produced from an aliphatic isocyanate and a hydroxyl-group-containing and/or aminofunctional reaction partner. It ensures the functions of the thermal collector, coupler and conductor for heat energy.

3D printing means, inter alia, a method performed by means of a machine, similar to printing, which constructs and/or forms hollows in and/or reduces the three-dimensional material workpieces. This method is performed in a computer-controlled manner from a liquid material, or at least one liquid material and/or at least one other material, in particular solid materials in accordance with predefined dimensions and shapes (CAD). During the construction process, physical and/or chemical and/or thermal curing or melting processes occur, in particular by means of laser and/or pulsed laser and/or selective laser melting and/or electron beam melting. Typical matter, in particular materials, for 3D printing are plastics materials, synthetic resins, ceramics and metals. Here, 3D printing is also a generative manufacturing method. 3D printing machines work in particular with a material or a material mixture, in particular as a mixture by means of nanoparticles. 3D printers are used for the production of workpieces.

In a particular embodiment, the modules, PV module, at least one thermoelectric generator module and/or at least one module of the circuit board through which fluid passes can be integrated, in particular by means at least one adhesive (KL) and thus in the form of at least one unit, and can consist of at least one functional module, in particular of at least one semiconductor, in particular of silicon of different doping. Here, a geometrical part of the semiconductors has the functionality of at least one circuit board through which fluid flows, in particular by means of recesses in the semiconductor, in particular in the module of the thermoelectric generator. This has the advantage of saving on raw materials and reducing the thermal resistances and/or interfaces for example by the adhesive (KL) on the semiconductor and/or on the circuit board and/or providing a performance-enhancing connection.

In a particular embodiment, the module of the thermoelectric generator in the region of the cooling zone and/or heating zone has recesses in the material, in the form of at least one line, in particular for the passage of the fluid, in particular for cooling and/or heating. Here, the line can be in the form of at least one branching, in particular distributed in a planar manner. In a particular application, nanoparticles, in particular nanohorns, and/or other material can be contained inside the line, in particular on the surface of the inner side, in order to advantageously increase the surface extent, in particular in order to increase the thermal conductivity and/or heat transfer.

In a further particular embodiment, the module of the thermoelectric generator, in the region of the cooling zone and/or the PV module, has recesses in the material on its inside, in particular on the surface in the hot zone, said recesses being provided in the form of at least one line, in particular for the passage of the fluid, in particular for cooling and/or heating. The line and/or recess can be provided here in particular in and/or on the p-doped and/or n-doped layer and/or transfer layer and/or in and/or on the positive and/or negative electrode of the module, in particular PV module. This has the particular advantage that the modules, in particular solar cells, are controlled to an optimal performance-enhancing system temperature, and in return an optimal cooling is achieved in the modules, in particular of the thermoelectric generator.

For the heat utilisation, all modules must be assembled in the case of solar cells. However, it is also possible and advantageous to utilise only the cooling if this is desired. It is precisely in this way that the module can also be used advantageously solely as a solar collector.

In a particular embodiment, the modules (PV module, thermoelectric generator module, circuit board through which fluid flows) can be thermally and/or electrically and/or mechanically coupled, in particular by means of at least one adhesive and/or by means of at least one adhesive layer (KL) and/or at least one connection, in particular an integrally bonded connection. For example, this system can also be used as a retrofit kit in existing systems, in particular solar plants, and can be fitted by means of at least one connection, in particular by means of at least one adhesive (KL).

In a particular embodiment, the heat and/or cold can be collected by means of at least one latent store, in particular a heat store and/or cold store, and for example can be released again at night time, when the cell is not irradiated by the sun, with the advantage of multiple utilisation of heat and/or cold.

The latent store can be provided for each module and/or adhesive (KL), in particular in the PV module in order to store heat and/or in the thermoelectric generator module in order to store cold at the cold end.

Here, the latent store can also be an independent module and/or system, in particular an ice store and/or blast furnace and/or heat extractor.

In a particular embodiment, the modules (here in particular the PV module, thermoelectric generator module) can be thermally and/or electrically and/or mechanically connected, in particular coupled, in particular by means of at least one semiconductor, in particular silicon, with different doping and arrangement for solar-voltage functionality and/or thermal voltage functionality. Here, in this particular embodiment, the cooling can be provided in particular in that the cooling system for the fluid is provided and/or integrated in the semiconductor by means of a recess and the fluid in particular is a poor electrical conductor and/or is not electrically conductive, for example has an electrical conductivity of less than 15 μS/cm (+/−30)% at 20° C., in particular less than (1*10⁻8)S/m. Here, the fluid is provided in particular for use as a heat transfer medium and/or with anti-corrosion additives, by means of a low electrical conductivity value and/or nanoparticles and/or external electrical control system and/or internal control system. Here, the fluid is in particular based on propylene glycol. In a further particular embodiment, the surfaces can be microstructured by means of laser in order to further increase efficiency, in particular thermoelectric efficiency.

In a further particular application, the at least one surface of a module, in particular also solar cells, in particular PV solar cells with black surfaces (OB), in particular formed from silicon, can be used for improved utilisation of the infrared radiation. A black surface (OB) made of silicon is in this case a surface modification of crystalline silicon by means of high-energy bombardment with ions and/or ultra-short laser pulses. Here, needle-like structures, in particular nanoneedles with a length greater than 10 μm at a diameter of less than 1 μm, are produced on the surface and significantly reduce the reflection of the substrate by approximately (20 to 30)% with quasi-perpendicular incidence and lead to a microstructuring of surfaces. Microstructuring of the surface can be provided in particular by means of laser and/or 3D printing and/or etching.

In a further particular embodiment, the black surface (OL) can be used to practically shut down power generation, in particular in the event of a fire, and therefore can be used to protect the system and people, in particular in the event that, in the case of a fire, human helpers could be placed at risk of electric shock transferred via extinguishing water. Here, the surface (OL) can be changed in a controlled manner by means of at least one adhesive (KL), in particular in respect of its colour, in particular in a one-time change to the surface, into a surface that is opaque to solar radiation, in particular a black surface. This can be achieved by means of at least one adhesive (KL) and/or at least one adhesive layer (KL), in particular also by means of etching and/or coating with nanoparticles. The surface (OL) here can also be an independent module, in such a way that the surface colour and/or surface transmissibility are/is controlled such that these are transparent and/or black and/or opaque by means of an applied polarisation and/or voltage, and/or in a one-time process, for example in accordance with the invention by means of use of the controlled orientation of the nanoparticles, in particular by means of heat, in particular at a temperature of more than 140 degrees Celsius, in particular by means of chemical substances, in particular triggering substances contained in extinguishing water. For this purpose, at least one adhesive (KL) and/or at least one adhesive layer (KL) are/is distributed over the surface (OL), in particular with a thickness of less than 0.01 mm, in particular greater than a multiple of (200 to 500) μm, in particular between (200 to 1,500) μm. In particular for chemical substance triggers, the thickness is in particular less than 2 mm.

In one embodiment, the circuit board, in particular the carrier plate through which fluid flows, can advantageously at the same time be a heating and/or cooling circuit, in particular at least a latent heat store and/or at least a latent cold store, as is necessary from a technical viewpoint in each case, wherein in particular the surface increase can be utilised advantageously, wherein structuring measures advantageously influence the energy density in the fluid, which in turn has an influence on the thermal flow.

In biology, a surface is increased and is an indication that exchanges take place for substances or energy. An improvement is provided by means of the enlargement of the surface. Here, the following basic principles for surface enlargement are possible and are and/or can be used in accordance with the invention. Folding and/or chambering inwardly, comparable in biology to pulmonary alveoli, provided here in accordance with the invention by means of nanoparticles, in particular a nanocoating, in particular by means of nanoneedles and/or comb-like deposition in the interior of the line. Folding and/or branching outwardly, comparable in biology to the villi and microvilli and root hairs, provided here in accordance with the invention by means of nanoparticles, in particular a nanocoating, in particular by means of nanoneedles and/or comb-like deposition on the outer side of the line. Meanderings, comparable in biology to the brain, provided here in accordance with the invention by means of capillaries and/or capillary networks, in particular with the function of ensuring equal pressure losses at each module. Shaping of bodies, comparable in biology to erythrocytes, provided here in accordance with the invention by means of nanoparticles, in particular nanoparticles in the fluid. The shaping is provided here in accordance with the invention by means of a particular structured surface shape, in particular a cuboid shape and/or sphere shape and/or conically tapering shape of the cooling ribs. These basic principles of surface enlargement encountered in nature are used advantageously in the invention.

Shaping, in particular of the inner surface in the fluid channel, is provided here in accordance with the invention by means of a particular shape of the transport lines, in particular for fluid transport. The maximum possible performance is possible by way of example in the case of a rhombus cross-sectional shape. Further cross-sectional shapes are advantageous: rhombus diameter shapes with an efficiency of (35 to 40) watts; rectangle diameter shapes approximately (20 to 23) watts; zigzag diameter shapes approximately (28 to 35) watts; zigzag diameter shapes approximately (19 to 25) watts. A further type of application for the optimum is a honeycomb-rectangle cross section, in particular of at least one thermally and/or electrically conductive capillary network, for example made of copper, particularly advantageously within the circuit board. This is the case in particular with the following dimensions and a tolerance of (+/−30)%: height, internally of 2 mm, width, internally of less than or equal to 30 mm, effective length per module of less than or equal to 0.1 m, in particular less than 0.4 m, capillary network structure, with water being the fluid, in particular steam temperature 50° C., upright operation, in particular relative to the force of gravity, in particular with the fluid provided by means of particles, in particular nanoparticles.

The disadvantage of the low thermal transport capability of a micro heat tube, here on account of the small diameter, can be compensated for advantageously by the connection in parallel of a plurality of micro heat tubes and/or swirling therein. The smaller the effective pore radius, the greater the pumping effect of the capillary structure. Here, the flow resistance also increases. The optimum is present when the maximum heat flow can be transferred, i.e. a maximum mass flow driven by the capillary force flows through a capillary cross section. By way of example, a maximum performance with a mesh number of 181 meshes/inch (+/−30)% is possible.

In a particular embodiment, the surface can be enlarged for example by the structure of hollow ceramic spheres (“bubbles”) and/or nanoparticles contained in an amount of less than 50 vol. %. Besides the advantageous stable, articulated structure, a surface enlargement is also provided. This is provided by means of cooling ribs (cooling fins) for enlarging the surface of a body in order to improve the heat transfer to the surrounding environment and therefore the cooling and/or cooling function.

In a particular embodiment, a performance increase can be provided by means of adiabatic cooling, in particular by means of at least one fluid, in particular water, which is nebulised in the finest form possible, in particular by means of ultrasound, in particular by means of at least one piezoelement. For example, this can be achieved by means of ultrasound energy and/or ultrasound, in particular by means of at least one piezoelement, in that vibrations of a specific frequency and/or a frequency mixture and/or at least one amplitude shape are/is generated by means of at least one piezoelement. Here, the piezoelement, in particular at least one ceramic piezocrystal, is applied at an AC voltage over such a time that the piezoelement deforms, in particular at a frequency less than (2 to 6) kHz, in particular less than 20 MHz, in particular greater than 35 MHz, and the fluid, in particular water, is shaken and torn in particular via the piezoelement, in particular the ceramic disc. In so doing, tiny drops of fluid are produced, in particular drops of water, which remain for a long time in the fluid, in particular in the air, and are transported in the capillary system. Here, the piezoelement can be integrated on the PCM fitting, in particular as an encircling ring and/or can be integrated in the modules, in particular in the cooling module, and has the advantage of further increasing the efficacy, in particular for treatment of the fluid, and can also be further improved by means of at least one structured surface.

A further advantage is a higher rib density, which leads to an enlargement of the heat delivery surface and therefore to a higher efficiency for cooling, in particular as a result of the shape tapering conically and/or in a pointed manner to the cooler tip. Furthermore, in a particular application, a fluid can flow through the cooler. In a further particular embodiment, the cooler is a conductor, in particular a circuit board, with a fluid flowing therethrough. In a further particular embodiment for improving the heat transport and/or heat delivery, the conductor surface comprises at least one cooling function, in particular in such a way that the surface delivers heat in particular by means of at least a dark surface colour and/or a controllable surface and/or by means of at least a roughness. This is provided by means of nanoparticles, in particular nanostructures and/or nanoparticles. In a further particular embodiment, current can flow through the module by means of the Seebeck effect, thus resulting in an active cooling.

The roughness is determined in accordance with DIN 4760, ISO 25178 and characterises the unevenness of the surface height, in particular the roughness depth. Advantageously, in the case of surfaces with a roughness depth Ra of less than 0.8 μm, with regard to hygiene properties it is practically no longer possible for the germs to hold on. This can be used advantageously as an adhesive surface (KL), in particular on the surface (OB). Furthermore, a functional surface function can also be attained with a structured roughness, in particular the functionality of a shark's skin surface and/or fish skin surface.

Nanoparticles, in particular nanohorns or what are known as nanohillocks, are produced by means of electrically charged particles. This can be achieved by means of ion irradiation and/or laser or other kinds of microstructuring of the surfaces and/or manipulation of the surface. Here, ions of high energy in particular are irradiated, thus resulting in a surface structure in the form of impact craters and/or elevations, formed here in particular as nanohorns, or also nanohillocks. The structured surface, in particular the nanohorn or nanohillock, is formed in such a way that a tiny region of the material melts, loses its ordered atomic structure, and expands. This results in particular in what are known as nanohillocks, that is to say small humps on the material surface. The high electrical charge introduced in the form of the ion into the material has a strong influence on the electrons of the material. This means that the atoms detach from their positions. If the energy is not sufficient to melt the material locally, no nanohorns or nanohillocks can form, and instead smaller holes are formed in the surface, this being highly dependent on the state of charge, and hardly dependent at all on the speed of the ion bombardment. By contrast, the creation of holes is determined decisively by the movement energy of the ions. This can take place and/or can be used advantageously on the adhesive surface (KL), in particular at the surface (OB).

In a further particular embodiment of the nanoparticles and/or microparticles and/or nanohorns, the size is not smaller than the wavelength of the thermal radiation, in particular is (30,000 to 780) nanometres, so as advantageously to irradiate the heat efficiently, in particular at a frequency of the infrared radiation, in particular between the radiation frequency of from 1 to 400 billion Hertz.

In a further particular embodiment, the surface inside the line has the structure of shark's skin and leads to a reduction in the frictional resistance of more than five percent. Here, the surface has a riblet structure with scales, with fine grooves and sharp groove tips and/or a uniform groove pattern with fine tips. This structure is produced by means of coatings and nanoparticles and/or nanoplates.

If vortices form as a result of the roughness of the surface over which the fluid flows, this has effects on the desired temperature equalisation. Less heat is delivered convectively. As a result, the heat transfer resistance is advantageously increased.

In a particular embodiment, compressed air can be used as fluid. Here, cold air down to minus 46° C. can be produced advantageously by means of a vortex tube for cooling of the capillary network, specific points, or the housing, from conventional compressed air without moving parts, i.e. without direct electrical energy. The vortex tube, as is known, generates a differentiated material flow and/or fluid flow, which separates hot and cold particles of a substance from one another. In thermoelectrics, a permanent heat flow through a thermoelectric generator is required, in particular for power generation.

In order to be able to feed the hot or cold material flow, for example air, to the circuit board in a defined manner, a PCB fitting has been developed which makes use of the material flows in the sense of the description of the intellectual property right. By defined guidance of the material flows, hot and cold surfaces are thus produced on or in the circuit board. Reference is made by way of example to a carrier plate supplied with cold material flow in the interior. The hot counter-side can then be used for example to absorb the radiation heat of a hot body, in particular the sun. The hot side, however, can also be produced by the hot material flow of the vortex tube. Equally, the example can also be arranged in reverse. A geometric design of the PCB fitting advantageously ensures directed use of the material flow exiting from the vortex tube.

In a further particular embodiment, the thermal conduction can be controlled by separating the metals and/or semiconductors, in particular the two metals and/or semiconductors, from one another by means of at least one airless gap, in particular a minimal airless gap. In particular, the gap (KAP) between the semiconductors of a Peltier element, in particular between the n-doped and/or p-doped semiconductors, can be enclosed for example between the carrier material (BA) and the adhesive (KL) for the generation of electrical energy. This is achieved in particular by means of a vacuum of approximately (0.2 to 3) bar, in particular also with approximately (0.1 to 0.03) bar. The thermal conduction via lattice vibrations is thus fully eliminated. However, from the viewpoint of quantum mechanics, the vacuum gap is only wide enough for individual electrons to be able to pass through. The undesired conduction of heat between the metals or semiconductors is thus advantageously eliminated, and the efficiency rises.

The minimum airless gap, in particular of greater than 7 nm (+/−30)%, can be produced by way of example by means of nanoparticles, for example with a size of greater than 7 nm (+/−30)%, in particular by means of a melting process and/or combustion process of the nanoparticles, in particular via a “lost” thin layer, between the contacts, which is subsequently removed and leaves behind a thin gap of porous structures.

The electrons must have a mean free path length in these materials that is greater than the layer thickness, so that the tunnelling probability is still high enough. An efficient decoupling of the lattice vibrations occurs when the gap size lies within the range of the wavelength of the conventional temperatures at which such elements are to be used; the wavelengths of the electromagnetic emissions lie in the range of several hundred nanometres to a few micrometres.

In a further particular embodiment, the pressure between the semiconductors and/or metals can be lowered in order to reduce the heat transfer associated with the materials, in particular by means of conduction and convection. Here, the lowering of the pressure advantageously also leads to an improvement in the dielectric strength. The minimum dielectric strength, in particular in the case of air, is reached at a pressure of less than 1 mbar, with the dielectric strength being less than or equal to 0.3 kV/cm with (+/−20)%, and in particular at approximately 1 bar is (20-40) kV/cm with (+/−20)%. If the pressure is lowered further in the direction of a high vacuum with (1*10?3 to 1*10?7) with (+/−20)%, the dielectric strength advantageously increases exponentially. Here, it is also advantageous to form the edges of the materials, in particular nanoparticles and/or metals and/or semiconductors, in a rounded manner in order to avoid field emissions. A vacuum, for example a low vacuum here of less than 0.03 bar (+/−30)% or of (0.2 to 0.3) bar and/or a proportional material content, in particular between (20 and 30)%, in particular less than or equal to 5%, are/is introduced.

A general particular advantage is that, in terms of their material properties, the materials used lie within the nano range, have good thermal conduction, and are characterised in that they are very closely connected to the physical lattice structures of the material elements, in particular in the case of at least one hexagonal CNT and/or hexagonal graphite and/or boron nitrite and/or diamond and/or pentagonal CNH material proportion. The material proportions are advantageously in particular less than 5% and/or less than 40%.

Nanoparticles in the fluid that are connected very closely in the nano range to the physical lattice structures, in particular hexagonal CNT, hexagonal graphite, boron nitrite, diamond, and pentagonal CNH, are particularly advantageous in respect of thermal conductivity and can disperse well and thus contribute to an improvement in the energy density in the fluid.

In a further particular embodiment, the Thomson effect can be advantageously utilised. Here, the Thomson effect, named after William Thomson and not to be confused with the Joule-Thomson effect or the Gibbs-Thomson effect, describes the altered heat transport along a conductor through which a current is passed, in which there is a temperature gradient, here in Kelvin per metre (K/m). The temperature gradient drives the heat conduction and can cause flows, for example the Benard effect or Küppers-Lortz instability. In the case of the Benard effect, the cell structures in plan view are typically linear or hexagonal, or a flow centre forms in the middle of the structure. In the case of Küppers-Lortz instability, the static layer becomes unstable from a certain value of the temperature gradient, and a stationary convection flow starts to take form. Depending on the temperature difference between top and bottom, different patterns can be assumed, from a simple roll-like flow to a honeycomb-shaped hexagonal flow. In this case, the liquid in the middle of the honeycomb flows upwardly and downwardly at the edges. Here, in the case of the Thomson effect, depending on the metal and/or semiconductor, each conductor through which a current is passed will transport either more heat or less heat between two points with a temperature difference compared to the case without current flow, due to the thermal conductivity. This effect is superimposed with the heating of the electrical conductor by the current on account of its resistance. It is thus advantageous to use the heat transport and/or the resultant flows, in this case within the system according to the invention, in particular to control the flow of the fluid, in particular along the conductor and/or semiconductor through which current is passed, in that a flow of current and/or a controlled and/or external flow of current is provided, in particular in the start-up phase. In particular, a time-limited flow of current can thus be generated for example via an external power source, for example via a capacitor, at least one capacitor, and/or by means of at least one inductor, said flow of current being switched off for example after a successful start-up and thus controlling and generating an optimal flow.

A fluid is also understood to mean a material and/or substance, in particular a gas and/or a liquid and/or a solid material and/or material mixtures, in particular not opposed by any resistance in particular with arbitrarily slow shear. Gas is compressible and liquid is practically incompressible. Fluids by means of which the Navier-Stokes equation can be described and non-Newtonian fluids, which behave in a more complex manner, are dealt with in rheology. Furthermore, a fluid is also a coolant and/or heat transport means and/or electrical conductor and/or electrical insulator, in particular with gaseous and/or liquid and/or solid substances and/or substance mixtures being used as heat transfer medium, in particular to transport heat and/or cold away. Furthermore, in particular a cooling water, oil and/or alcohol can be used as fluid. A liquid, in particular based on propylene glycol, can be used in particular as a heat transfer medium, for example with anti-corrosion additives and advantageously with an electrical conductivity value in particular of less than 100 μS/cm, in particular based on propylene glycol. Particularly advantageous fluids and/or materials for cooling systems are those based on calcium chloride, in particular those constructed from steel (ST 37 or comparable), and those based on potassium carbonate (potash) are particularly advantageous for protection against corrosion in steel and also to a certain extent non-ferrous metals. In a further particular embodiment, a material with a cooling and/or heating function can be introduced between the semiconductors and/or metals, in particular a gaseous material and/or gas and/or fluid, in particular a non-electrically conductive fluid.

Impressing a vibration onto a fluid is achieved in the simplest case in particular by means of a gas spring and/or piezoelement. The gas cushion as fluid forms the compressible phase, and the liquid as fluid forms the non-compressible phase, which is coupled to the liquid to be reacted. The hardness of the spring and thus the inherent frequency of the resonant system can be adjusted by varying the fluid, in particular gas volume. Piston pulsators, gas pulsators, or membrane or rotary vane pulsators, or piezoelements can be used, inter alia, to excite the vibration. The spring can also be formed by one or more mechanical, pneumatic or hydraulic elements. It is additionally possible to excite resonant pulsations by inertial forces or by exciting vibration states by magnetic fields by means of at least one inductor, in particular by means of an electrically conductive coil, which is controlled by means of a particular control device, in particular at suitable clock frequencies to avoid interfering influences (EMC).

Vibration states can also be excited on the material and/or the fluid advantageously by means of at least ultrasound energy and/or ultrasound of different intensity in watts and/or time duration and/or concentration form over time. In particular in order to produce stable suspensions, in which a re-agglomeration is prevented or eliminated, sonication can be used, in particular (1 to 15) minutes of sonication (+/−30)%, in particular with ultrasound energy, in particular by means of at least one piezoelement and/or ultrasound wand. Materials can be heated advantageously by means of electromagnetic radiation by the excitation of vibration states, by means of at least one frequency from 300 GHz to 300 MHz or a wavelength from 1 mm to 1 m, also known as dielectric heating, this being based on the ability of the materials to convert the irradiated energy into heat. In order for this energy conversion to take place, the irradiated material must have a sufficiently great dipole moment. Control by means of the size of the dipole moment is thus advantageously possible. This is performed in particular at different intensity in watts and/or time and/or concentration of the material and/or the fluid. It is advantageous that the flow force and thus the heat transport potential is increased at the edges, in particular on the basis of the Richardson effect, and therefore instead of scale forming at the walls, for example in the case of the water being used as fluid, the calcium carbonate for example flows after the treatment in the form of a soft sludge in the system and does not settle and therefore does not prevent heat transport. In a further type of application, an improvement in the fluid and/or flow property can be provided by means of electric and/or magnetic induction, in particular by means of at least one coil, with the advantage of contactless cleaning of capillaries (KAP), lines, and pipelines. Since, in the prior art, the surfaces are heavily attacked disadvantageously by means of acid, etc., this leads to an increased surface roughness and also results in increased material wear. Due to the use of such methods, thicker and harder deposits form ever faster, thus leading inevitably to more frequent cleaning cycles, up to complete replacement of the capillary (KP) and/or line and/or pipelines and/or plant parts in question. Here, the system can used for the generation of induction, in particular of magnetic fields, in particular with at least one coil and at least one process computer, with the frequency spectrum of the magnetic fields being varied such that the necessary induction frequency is present for each required flow rate. The alternating current flowing through the coil, in particular inductors, generates a magnetic field, the frequency and polarity of which are permanently reduced, and which in particular by means of at least one coil, in particular wound inductors, generates continuously changing frequencies, alternating, modulated magnetic fields, and additional resonant pulsations. The parameters of induction are in particular a variable frequency spectrum, in particular between (20 to 500 Hz) and/or variable pulse frequency and/or variable pulse amplitude, and in the fluid a flow rate, flow changes, in particular an increase in the flow rate in the direction of the capillary (KAP) can be provided. Electrorheological fluids (ERFs) change the flow properties and thus the flow resistance and enable an optimal adaptation of the forces within a few milliseconds in the case of damping, reduction of vibrations, or positioning. The electrorheological liquid is a dispersion formed of a carrier liquid and polarisable particles, in particular formed of polyurethane, in particular a PU-based suspension with silicone oil. These particles have a mean diameter of less than or equal to 5 micrometres (+/−30)%, in particular less than or equal to 2 micrometres (+/−30)%, in particular less than or equal to 4 micrometres (+/−30)%, and are formed as dipoles. If an electric field is applied, what are known as polymer chains form within a few milliseconds. The flow channel is provided with two electrodes. When a voltage is applied the polymer chains cause a blocking of the flow cross section and thus increase the flow resistance for the fluid, so that the forces can adjust within a wide range depending on the intensity of the electric field.

A particular advantage is the fact that the pulsating particle-containing fluid, which is generated by means of induction, in particular by means of at least one coil, excites the particles to vibration, comminuting them in part at the same time, and a clogging (up to 100% frictional resistance) of the cooling line is thus prevented, and the fluid is stable even once the magnetic field has been switched off for up to a number of days, in particular the adhesion capability, in particular of the particles at the edge. An advantage and mode of action of nanoparticles in the fluid is a higher hydraulic load-bearing capability with a high operational reliability, improvement in the frictional resistance at the surface of the capillary, and an improvement in the thermal properties and in particular a reduction in the electrical properties of the fluid.

It is also advantageous that fluid with particles, in particular nanoparticles, in particular also referred to as nano thermofluid, can be used, in particular instead of water, as carrier with nanoparticles as cooling fluid, as fluids with dispersed nanoparticles to improve the properties of electricity, magnetism, heat conduction or combinations thereof. In particular, nanoparticles can be used as materials for this purpose. Nanoparticles, in turn, can also consist of at least one material. Furthermore, nanoparticles can also be, in particular, nanoscale materials and/or boron nitride (BN) and/or aluminium nitrate (AlN) and/or aluminium oxide (Al2O3) and/or hexagonal CNT and/or hexagonal graphite and/or boron nitrite and/or diamond and/or pentagonal CNH. A further particular advantage of CNHs is their geometry, which is utilised here advantageously for heat transport, and/or the fact that they cannot infiltrate human cells, animal cells and plant cells. Further substances that in particular can be nanoparticles include copper, metal oxides, silver nanoparticles, and silicon carbide (SiC). This has the advantage that the thermal conductivity is significantly increased, in particular with an improved heat transfer of approximately 20%. Ferrofluids can also be used, these being coated, ferromagnetic nanoparticles, in particular with a diameter less than or equal to 10 nanometres, and being present in a carrier liquid as a stable suspension, in particular a fine, homogeneous distribution of an insoluble solid in a liquid. The ferromagnetic substances used are usually iron, cobalt, nickel or also magnetite (Fe 3 O4). The advantage of ferrofluids is their sealing effect. With the aid of a strong magnetic field, the ferrofluid can be held in its position in spite of pressure differences. This accompanies the further advantage of adaptability and wear-free use. It can be used in particular for compression in order to protect against dust, and also for vacuum techniques. Furthermore, ferrofluids can be used for heat dissipation and for example have a thermal conductivity that is approximately 4.5 times that of air, with the advantage that the ferrofluid is held in its position by the magnetic field. Here, magnetite is used most often, since it can be produced very easily in the correct amount and is resistant. In order to produce a repelling interaction, the nanoparticles are coated. They can be coated for example with surfactants which have a hydrophilic and also hydrophobic part (amphiphilic). The polar part settles on the polar magnetic particles. The nonpolar remainder can interact with the carrier fluid (usually long-chain hydrocarbons), whereby a suspension forms upon introduction of the coated magnetite particles in the carrier fluid. The chains of the surfactants prevent interaction between the nanoparticles on account of steric repulsion.

Furthermore, the term “nanoparticles” is understood to mean in particular carbon nanohorns (CNHs) with a morphology similar to that of carbon nanotubes (CNTs), with the same carbon layer structure as CNTs. Single-walled nanohorns (SWNHs) consist of tubes with approximately (2 to 5) nm diameter, (30 to 150) nm length, and are closed by a cone at one end. The main feature of CNHs is that they form aggregates (secondary particles) with a size of approximately 100 nanometres to several μm. The cone can have different angles of aperture. The cone with the smallest angle of aperture has precisely five five-cornered carbon rings. Carbon nanohorns (CNHs), similarly to carbon nanotubes (CNTs), are very stable and hard materials. They are very good electrical conductors at nano level and have a thermal conductivity along their axis comparable to that of diamond. The strong Van-der-Waals forces between the nanohorns lead to a spontaneous self-arrangement. The following types of nanoparticles exist, inter alia: CNH (preparations): CNH type A, powder, very high purity greater than or equal to 99.5%, extremely fine, (air-classified fine fraction), CNH type B, powder, very high level of purity greater than or equal to 99.5%, very fine, (unclassified), CNH type F, water-based paste, approximately 8%; CNH type B; CNH type W; CNH type B wetted with H2O, with (10 to 20)% water content. Further types or forms can be configured according to use, for example CNH suspended in solvents or Pt-doped CNH. Properties of CNHs: CNH dimensions: length (5 to 150) nm, typical diameter (2 to 3) nm, purity greater than or equal to 99%, dimensions of the CNH agglomerates: cauliflower-like aggregates up to several 100 nm diameter, size of the agglomerates is up to several μm; structures: seed-like and dahlia-like; density: approximately 35 g/I; pore volume: approximately 1.1 cm³/g; pore diameter: approximately 12 nm; specific surface: greater than or equal to 200 m²/g, in particular (200 to 235) m²/g. There is also the advantage in particular of an increase in surface friction and strength by addition of carbon nanohorns (CNHs) and/or carbon nanotubes (CNTs). Carbon nanohorn (CNH)- and/or carbon nanotube (CNT)-reinforced plastics materials, for example thermoplastics. The strength and thermal conductivity of carbon nanohorns (CNHs) and/or carbon nanotubes (CNTs) can be used to improve the plastics material properties. Carbon nanohorns (CNHs) and/or carbon nanotubes (CNTs) can be sintered metal alloys. The strength properties can be utilised at low density to produce wear-resistant light sintered metal alloys, in particular in the case of 3D printing. Carbon nanohorn (CNH)- and/or carbon nanotube (CNT)-reinforced or carbon nanohorn (CNH)- and/or carbon nanotube (CNT)-coated carbon nanohorn (CNH) and/or carbon nanotube (CNT) buckypaper (carbon nanohorn (CNH) and/or carbon nanotube (CNT) thin films). The strength properties of carbon nanohorns (CNHs) and/or carbon nanotubes (CNTs) can be used to mechanically harden mechanically sensitive carbon nanohorn (CNH) and/or carbon nanotube (CNT) buckypapers. Hydrocarbon-based lubricants can be hardened. There is increased electrical conductivity in buckypapers at higher voltage potentials. Processing into carbon nanohorn (CNH) and/or carbon nanotube (CNT) ceramic, in particular sintered composite materials, is possible. Hardened thermoplastics. Carbon nanohorn (CNH)- and/or carbon nanotube (CNT)-hardened coatings. Carbon nanohorn (CNH) and/or carbon nanotube (CNT) sinter with 100% carbon nanohorns (CNHs) and/or carbon nanotubes (CNTs). Carbon nanohorn (CNH) and/or carbon nanotube (CNT) Al metal sinter with 97% Al+3% carbon nanohorns (CNHs) and/or carbon nanotubes (CNTs). Carbon nanohorn (CNH) and/or carbon nanotube (CNT) zeolite sinter with greater than or equal to 97% zeolite, greater than or equal to +3% carbon nanohorns (CNHs) and/or carbon nanotubes (CNTs). Disaggregation of carbon nanohorn (CNH) and/or carbon nanotube (CNT) aggregates into individual carbon nanohorns (CNHs) and/or carbon nanotubes (CNTs). Textiles enriched with carbon nanohorns (CNHs) and/or carbon nanotubes (CNTs). Carbon nanohorn (CNH)- and/or carbon nanotube (CNT)-reinforced glass and/or paper membranes, coated glass and/or rice paper. Use of the carbon nanohorn (CNH) and/or carbon nanotube (CNT) properties for high-performance capacitors (supercapacitors). Use of the carbon nanohorn (CNH) and/or carbon nanotube (CNT) properties to improve Zn film batteries. Use of the carbon nanohorn (CNH) and/or carbon nanotube (CNT) properties for hydrogen storage. Carbon nanohorn (CNH) and/or carbon nanotube (CNT) composite plastics for compounding with nanomaterials. Carbon nanohorn (CNH)- and/or carbon nanotube (CNT)-hardened thermosets, carbon nanohorn (CNH) and/or carbon nanotube (CNT) applications in plastics materials and coatings in which a high electrical or thermal conductivity and/or a high mechanical strength are/is necessary. Enabling a functionalisation of the surface, for example anti-bacterially. Nanoparticles are in particular also nanostructures, such as nanofibres, CNTs and carbon nanohorns (CNHs), and in particular consist of single-walled, horn-like tubes of approximately (3 to 25) nm diameter and 20 to 150 nm length, which are closed by a cone at one end. They have a surface of advantageous size and in particular are advantageously transmissive to gases and/or liquids and advantageously have good electrical and thermal conductivity and high mechanical stability, as well as a high specific surface. The cone can have different angles of aperture, in particular an angle of approximately 20°. They have a high microporosity and are advantageously homogeneously dispersible in water, in particular in pure water without addition of dispersants, and in nonpolar solvents. Nanofibres, in particular carbon nanofibres (CNFs), can also be formed by long, fibre-like carbon layers, wherein the individual layers are arranged transverse to the fibre direction (platelet-type) or nested in one another in an angular manner (herringbone-type), with a diameter in the range of (150-300) nm and greater, but smaller than 400 nm, in particular 550 nm. By means of their irregular surface structure with multiple corners and edges, they are an advantageous material for rapid adsorption/desorption processes. Applied metallic intermediate layers between the graphene layers improve the bonding of the CNFs to ceramic and metallic substances and are advantageously used in composite materials, in particular as a layer between the compounds of the modules. In addition, platelet CNFs can also be used well in self-lubricating materials, in particular by means of vortex tube. For example, in tensile tests performed on a composite formed of polyethylene and CNT, in the case of a carbon nanohorn (CNH) and/or carbon nanotube (CNT) and mixtures thereof in a proportion of from 1 to 40 wt. %, it was possible advantageously to measure a reinforcement of less than 25% compared to homopolymeric polyethylene. It is also possible to produce electrically conductive plastics, in particular by means of the addition of less than 40 wt. % of carbon nanohorns (CNHs) and/or carbon nanotubes (CNTs) and mixtures thereof, in particular also polyethylene-carbon nanotube composites, in order to make a plastics material and/or fluid electrically conductive.

It is also possible to produce a black surface, for example with improved reflection better than 0.16%, for at least one carbon nanohorn (CNH) and/or at least one carbon nanotube (CNT) and nickel-phosphorous mixture, with a rough surface structure, in particular by means of nanotubes of different length, which are arranged closely together, for example for a reflection of less than 0.045% of the incident light. The field of use and the functionality of the black surface by means of carbon nanohorns (CNHs) and/or carbon nanotubes (CNTs) and mixtures thereof lie in high absorption, in particular in solar collectors and for the shielding of radio waves, in particular in a very wide frequency range.

In a particular embodiment, electrical conductive paths and/or electrical lines can be attained in particular on account of the outer geometry of CNHs and the achievable packing density, in particular contact between the CNHs is achieved by means of an impulse voltage. Electrical current paths and/or lines are thus created, which at the same time are also thermal paths and/or thermal lines.

Nanoparticles are particles smaller than 1 μm, in particular also CNHs and/or CNTs and mixtures thereof.

Here, the heat radiation or thermal radiation can advantageously reach a maximum by means of a dark, matt, in particular black RAL 9005 surface. The maximum absorption can be achieved for example by means of carbon black, colouring with aniline black, and/or by means of carbon nanohorns (CNHs) and/or carbon nanotubes (CNTs).

The tensile strength and/or bending strength of shaped articles is advantageously improved with a proportion by weight of just 0.1% carbon nanohorns (CNHs) and/or carbon nanotubes (CNTs) and/or oxidised carbon nanohorns (CNHs) and/or carbon nanotubes (CNTs), and the tensile strength and the bending strength of the shaped articles is increased by more than 50% compared to shaped articles without CNTs and by up to 15% compared to shaped articles with non-covalently bonded CNTs.

The conductivity of carbon nanohorns (CNHs) and/or carbon nanotubes (CNTs) is advantageously dependent on diameter and chirality. These give rise to different band structures and band gaps. According to theoretical hypotheses, all “armchair” nanotubes are metallic conductors. All other tubes are also semiconductive and have a band gap that is inversely proportional to their diameter. On account of the one-dimensional electronic structure, electrons are transported in particular in the case of metallic SWCNTs in the longitudinal direction without collision. This leads to a high current transport without significant heating of the conductor. The estimated maximum current-carrying capacity is less than 1 A, in particular 109 mA. As electrons transition between two adjacent nanotubes, however, corresponding barriers have to be overcome, which leads to heating.

The particular advantage with use and application of the vortex tube is that temperatures in the minus range can be produced and that the Delta T can be increased to (120 to 130) Kelvin, and, with linear dependency, designs of more than 1 kW power per m² would be possible. The thermo-fluid dynamics are advantageously positively influenced in this case.

The PCB fittings, with fitting screws being used as screwable connection elements for adaptation of hose and tube screw-based coupling systems, serve in particular as a screwable connection element for connection to boards, in particular for supplying the cooling and/or heating circuit within a material object, in particular a board. It is also possible, by means of the PCB fitting, to generate at least one pulsating fluid, in particular by means of at least one vortex tube function and/or by means of at least one electrically conductive coil, which in particular is in and/or on the head of the PCB fitting.

In particular formed as a device for generating a pulsating fluid, in particular a fluid jet, the PCB fitting consists of at least one material, in particular nanoparticles, and of pressurised fluid, with a line system containing at least one nozzle, which has a nozzle mouth, from which a pulsating fluid, in particular in the form of a fluid jet formed of pressurised fluid, can exit, and with a chamber, in which a pressure wave generation device is formed for the generation of fluid pressure waves, which pressure wave generation device communicates with the line system by means of an exit opening for the generated fluid pressure waves, containing at least one electrical adjustment device for controlling the amplitude AP of the fluid pressure waves in the line system before the at least one nozzle mouth, by means of which the control is performed on the basis of the quotient of the path length in metres to the fluid pressure waves between the exit opening of the chamber and the at least one nozzle mouth of the at least one nozzle in the line system and the wavelength, and/or by means of at least one electrical conductive coil, by means of current pulses. In a particular embodiment, compressed air can be used as the fluid. Here, cold air down to minus 46° can be produced advantageously by means of a vortex tube, in particular by means of the PCB fitting with vortex tube function, for cooling of the capillary network, specific points and/or areas and/or volume cooling, moreover can be generated from normal compressed air without moving parts, without electrical energy. Vortex tubes are devices which in particular can work with a standard compressed air supply. The air flows into the vortex tube and is divided into two airflows: cold air comes from one end (KA) of the tube, and hot air comes from the other end (WA), advantageously without moving parts. The vortex tubes have at the hot end (WA) an adjustable valve (R7), by means of which the airflow and therefore the temperature of the fluid that exits at the “cold” end (KA) is controlled. The cold proportion (KA) is thus advantageously adjusted, that is to say the specific percentage of compressed air that exits at the cold end (KA) of the tube. The vortex tube, in a particular application, but also without an adjustable control valve (R7), can be used here with a fixed default setting. Inside, there is arranged the exchangeable “generator”, for example made of brass, which controls the air flow rate and determines the desired temperature range at the cold and hot end. Various generators are available for different compressed air volumes. In addition, there are two basic types: one for achieving the lowest possible temperature (C generator) and one for optimising the cooling performance (H generator). The vortex tube has the advantage that no moving parts are provided, it works with air, enjoys maintenance-free operation, and has an adjustable temperature range. The PCB fitting as vortex tube and/or by means of a vortex tube has the following function: the compressed air enters tangentially (DR) at the inner point (A). Within the tube, this compressed air is set in rapid rotation with the aid of a generator and moves along the outer wall in the direction of the hot end (WA). Some of the air exits here at point (WA), whereas the rest of the air flows back through the centre and in so doing is cooled (KA) by expansion. The cold air exits at point (KE). Temperatures and volumes can be varied by adjusting the valve (R7) at the hot end (WA) and by use of different generators. In order to control airflow and temperature, the ratios of the volume flows and the temperatures in the vortex tube are dependent on one another. If the adjustment valve (R7) at the hot end (WA) opens, the cold air volume flow (KA) decreases, and the temperature reduces. The closing of the valve (R7) intensifies the cold air flow (KA), but the temperature thereof rises. The percentage of air that flows out at the colder end (KA) of the vortex tube is referred to as the cold air proportion. Depending on the temperature of the inflowing air (DR), a cold air proportion between 60% and 80% provides an optimal combination of flow volume and air temperature for a maximum cooling effect when an H generator is used. A lower cold air proportion indeed generates cooler air, but provides a poorer cooling effect on account of the lower flow volume. The applications require 60% to 80% adjustment of the controller (R7) for an optimal cooling result. The optimal cooling effect is achieved when the temperature difference between the fed compressed air (DR) and the cold air (KA) is between 28 Kelvin in the case of relatively cool compressed air, and 45 Kelvin in the case of relatively warm compressed air. Furthermore, in a particular application, the collected heat from radiation, which is then provided materially, in particular in a thermal store, can also be utilised. In particular, it can be stored in latent heat stores and used later, for example for heating or energy generation at night-time via the same system. Here, temperatures of (−50° to +260°) F. (−46°-+127° C.), flow rates of (1 to 150) standard cubic feet per minute (SCFM) (28 to 4.248) 1/min, and cooling power up to 10,200 Btu/hr (2.571 Kca/h) are possible and can be controlled, in particular via an adjustable valve (R7), in particular an electrically adjustable valve (R7) on the hot air side.

In a further particular embodiment of the PCB fitting, the Coanda effect, that is to say the wall adhesion of a fluid, in particular a liquid at high speed, can additionally be utilised in order to generate air movement in the surrounding environment. Here, for example, the fluid is pressed by means of a small amount of compressed air (DR) through an inner nozzle ring (R1) at more than the speed of sound, and a vacuum forms, which draws large amounts of the surrounding free fluid, in particular air, through the nozzle (R1), with the particular advantage that if the end of the nozzle is blocked, the flow is easily reversed, i.e. there is a low backpressure, which is far below the safety standard and thus fully observes compressed air safety requirements.

The heat energy accumulation is performed for example within the polymer matrix, for example with IR-absorbing and/or semiconductor pigments. These are, for example, platelet-like mica particles, which in particular are coated with an antimony-containing tin oxide layer, or modified titanium dioxide nanoparticles, which act as electron donors and enable a high level of absorption of infrared radiation in the wavelength range from 800 nm to 1 mm.

The thermal coupling is ensured for example by means of the cross-linking of the polymer. Here, the task of the thermal conductor is to ensure thermal conduction within the polymer matrix. For this purpose, carbon nanotubes (CNTs) and/or carbon nanohorns in particular are/is incorporated into the polymer matrix. The thermal conductivity of the CNTs, at up to 6,000 W/(m-K), is advantageously twice as great as the thermal conductivity of diamond and ensures a stable flow of heat, in particular to the thermoelectric generator. The CNTs are for example stabilised in the matrix in a special dispersing method. The use of further materials, in particular nanoparticles, in particular formed from metals and/or ceramic materials, is possible.

The possible composition of the thermal accumulator, in particular adhesive, consists for example of a two-component coating material comprising the following: component A: aliphatic isocyanate and/or mixtures thereof; component B: binder which can be cross-linked with component A, consisting of: (50 to 98)% binder based on a hydroxyl-group-containing and/or aminofunctional reaction partner and/or mixtures thereof; (0 to 20)% IR-absorbing pigments and/or a comparable material; (0 to 40)% nanoparticles, in particular carbon tubes and/or carbon nanohorns and mixtures thereof; (0 to 40)% nanoparticles formed from semi-precious metals and/or ceramic substances having a high thermal conductivity; (0 to 7)% stabilisers; (0 to 3)% auxiliaries.

A possible production example in accordance with the invention is in particular that up to 35% aminofunctional binder is present in the preparation vessel containing a batch. In particular, the pigments and/or additives are added to and mixed with this batch. By suitable energy input into this system, for example by means of an agitating mill, ultrasonic transmitter or roller mill, the corresponding primary particles are produced. The rest of the binder components are then added to give 100% base and are mixed. The necessary temperature parameters must be observed depending on the used pigments and/or fillers and/or additives, in particular below 80 degrees Celsius. Otherwise, a person skilled in the art can make a decision on the basis of the generally known prior art, after performing suitable series of tests as appropriate.

Depending on the field of application of the thermoelectric generator, for example nanoscale and/or nanoscalable and/or other raw materials having functional properties, for example for improving the UV stability, for increasing surface hardness and thus abrasiveness, or also additives for protecting against moss formation, can also be added in the formula to the two-component system, in particular in the adhesive (KL). The particular advantage of this is the functional property.

The generation of nanoparticles, in particular the separation and homogenisation of CNTs/CNHs, is performed by energy input in the range of (500 to 2,000) W/s. With the two-component system according to the invention, a coupling/absorption of the IR radiation and forwarding to the thermogate of more than 90% is advantageously ensured.

Alternatively, the PV cells can also be connected, in particular adhesively bonded, directly on the circuit board, through which fluid flows, by means of the two-component system. The circuit board then acts purely as a cooling system and consequently as a thermal solar system for heat recovery. Following the assembly of the PV cells, the cells and the thermoelectric generators are electrically connected to form an overall electrical composite. The advantage of this system is the compactness alongside maximum energy utilisation of the provided energy source, in particular the sun and/or other light sources. Firstly, the PV cell is continuously cooled by permanent dissipation of the heat via the thermoelectric generators (PE). Secondly, the dissipated heat is used for further energy generation by the thermoelectric generators (PE). Thirdly, the dissipated heat can be stored in a downstream latent store system, in a form still usable for other applications.

Further advantages result on the whole from an energy viewpoint. A multiple energy recovery is thus possible, as demonstrated by the test protocols. The energy recovery at the PV module corresponds in the case of a 200 watt PV module to up to 65 watt/m2. The energy recovery by the thermoelectric generator module is up to 400 watt/m2. The energy recovery by available collected heat power corresponds to up to 300 watt thermal power/m2.

### DESCRIPTION OF THE DRAWINGS

Preferred embodiments are presented in the description and drawings and serve to explain the present invention with reference to examples. The examples are not limiting.

In the drawings:

FIG. 1 is a schematic section through a first embodiment of a device according to the invention for generating electrical energy;

FIG. 1a is a schematic sectional view according to FIG. 1 for a second embodiment;

FIG. 1b is a schematic sectional view according to FIGS. 1a and 1 for a third embodiment;

FIG. 2 is a graph explaining the power losses;

FIG. 3 is a longitudinal sectional view of an embodiment of a fitting for fluidic connection of the carrier plate through which a fluid flows;

FIG. 3A to C show alternatives to the fitting according to FIG. 3; and

FIGS. 3D and 3E are schematic illustrations of the flow path and connection.

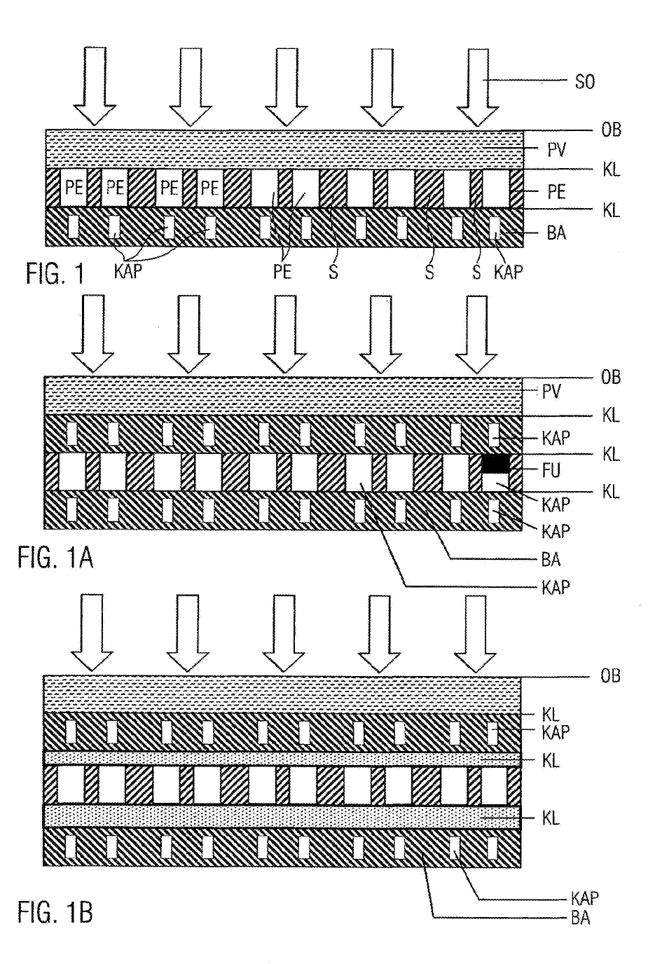

FIG. 1 shows a first embodiment of a device for generating electrical energy in the form of a thermophotovoltaic system. As shown by the sectional drawing, this system comprises a photovoltaic cell PV, which is connected by means of a heat-conducting two-component adhesive KL to a carrier plate BA. The connection is established here with intermediate positioning of a layer of thermoelectric generators PE. These thermoelectric generators PE are on the one hand adhesively bonded to the photovoltaic cell PV and on the other hand adhesively bonded to the carrier plate BA formed as a circuit board. The carrier plate BA itself has capillaries KAP, which serve for throughflow and therefore for heat dissipation of the circuit. In the present case, multiple thermoelectric generators PE are provided on the rear side of the photovoltaic cell PV and are each electrically conductively connected by means of their electrical connections to conductor tracks of the circuit board BA. The power produced by the thermoelectric generators PE is discharged accordingly via the circuit board BA.

Webs made of a thermally insulating material, such as plastics material, ceramic, or plastic foam or ceramic foam are provided between the individual thermoelectric generators PE. A fluid can flow through said webs, which are fluidly connected to the capillaries KAP of the carrier plate BA.

The fluid can be kept in flow movement by natural convection within the channels KAP. In the meantime, a plurality of units, for example according to FIG. 1, are preferably connected to form a system, wherein the individual flow channels of the individual units can communicate with one another. A system of this kind can comprise a pump, which brings about a forced flow through the individual capillaries KAP.

When actually in use, solar energy SO radiates onto the surface OB of the photovoltaic cell PV, and power is then generated in the conventional manner from the solar energy SO. Here, the photovoltaic cell PV heats up internally. This heating is used in order to generate further electrical energy by means of the thermoelectric generators PE, said further electrical energy being dissipated via the conductor tracks of the carrier plate BA.

It should be noted that the embodiment shown in FIG. 1 can also be used without the intermediate layer comprising the thermoelectric generators PE, wherein the carrier plate BA comprising the capillaries KAP is directly glued onto the rear side of the photovoltaic cell PV. The carrier plate BA, through which fluid can flow, can thus be used merely as a cooling element for the photovoltaic cell PV. Here as well, the connection between the carrier plate BA and the photovoltaic cell PV is preferably established by means of an adhesive bond.

In a further particular embodiment, which is shown in FIG. 1A, the thermoelectric generator (PE) is partially filled on the hot side, i.e. on the side facing towards the solar energy, with an electrically non-conductive and/or thermally insulating material FU, in particular to between 10 and 50% of the height of the space between the carrier plate BA and the photovoltaic cell PV at the height of the thermoelectric generator PE. The remaining height range of approximately 50 to 90% is formed as capillary KAP and is filled with a fluid for cooling KA and/or heating. This embodiment offers the advantage that the circuit board electrically connected to the thermoelectric generator PE does not itself have to be provided with capillaries, and therefore a fluid cannot flow through it.

FIG. 1, however, indicates the possibility of forming a carrier plate BA provided on the side facing away from the photovoltaic cell PV as a circuit board through which fluid flows. In the embodiment shown, further capillaries KAP are provided in a further layer of the carrier plate BA between the layer of the thermoelectric generators PE and the photovoltaic cell PV. The various layers are adhesively bonded to one another. Individual capillaries in each layer and/or in the various layers of the carrier plate BA can be thermally connected in series or in parallel.

In a further particular embodiment, the Seebeck effect is converted into the Peltier effect, for example by reversing the polarity of the current direction, with energy of a specific direction being fed to the system in order to generate cold and/or heat: here, cold and heat are generated on opposite surfaces, with the advantage that the optimal temperature of the system as a whole is generated by means of energy, for example the collectors heat up and, in particular in the event of ice and snow on the solar collectors, automatically rid themselves of snow, by means of temperature.

FIG. 1B shows a further embodiment with a significantly thickened adhesive layer KL. In this embodiment the molten adhesive comprises a filler proportion, which improves the ability of the adhesive layer KL to store heat. In the embodiment shown, nanoparticles having a weight-average volume proportion of from 0.1 to 5% are added as fillers of this kind. Due to this improved storage capacity of the adhesive layer adjacently to the thermoelectric generators PE, the heat and/or cold transport in the thickness direction is slowed by the embodiment. The particular adhesive layer KL in this case has a thickness of between 0.01 to 3 mm, preferably of between 0.2 and 1 mm.

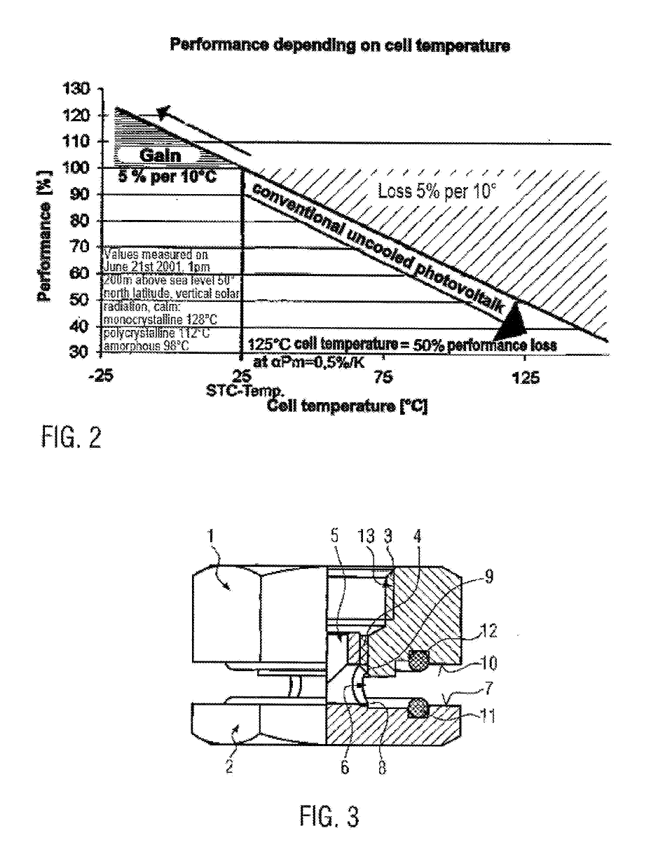

FIG. 2 shows the possible power losses on account of the cell temperature, wherein, at the reference point temperature of 25 degrees Celsius in a photovoltaic system (PV), a temperature decrease of 10 degrees Kelvin leads to an electrical energy gain of the photovoltaic system (PV) of approximately 5%, and with a temperature rise of 10 degrees Kelvin leads to a loss of the photovoltaic system (PV) of 5%. A particular adhesive thickness is less than 1 mm, in particular also in the range of 0.01 to 0.6 mm.

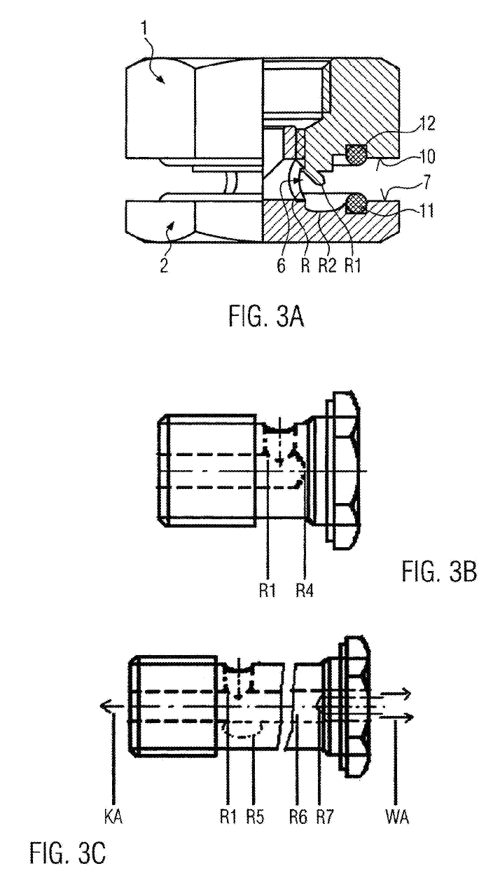

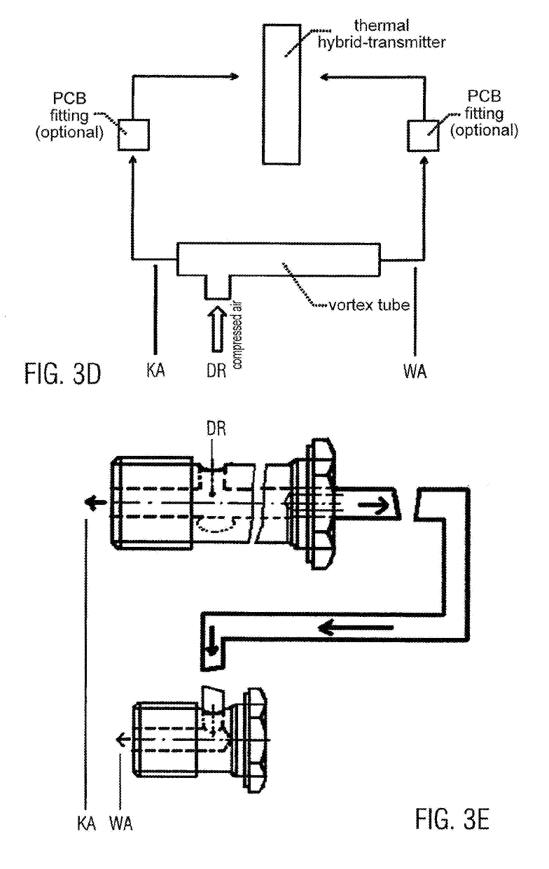

FIG. 3 is a drawing of a fitting for connection of the carrier plate, through which fluid can flow, to a line system. The fitting comprises a nut 1 and a screw 2. The screw 2 has a threaded shank 3, which is in threaded engagement with an internal thread 4 of the nut 1. The threaded shank 3 is tubular and has an inner bore 5, which communicates with a cross bore 6, which is omitted in the threaded shank 3 and opens towards the gap between the nut 1 and the screw 2. A protrusion 8 is provided between the opening of the cross bore 6 and a lower contact face 7 formed by the screw 2. A further protrusion 9 is formed by the nut 1. The further protrusion 9 protrudes in the direction of a base of the screw 2 from an upper contact face 10 of the nut 1. Peripheral annular grooves are formed in the lower contact face 7 and the upper contact face 10, with ring seals 11, 12 inserted into each of said grooves.

The nut 1 also has a connection thread 13 with a thread diameter of ⅛ inch for connection of a pipeline system to the fitting shown in FIG. 3.

For connection of the capillaries KAP of the carrier plate, this carrier plate is fitted onto the threaded shank 3 by means of a bore adapted to the outer diameter of the threaded shank 3. The nut 1 is then screwed onto the internal thread 4 of the threaded shank 3. The bore in the carrier plate is centred by the protrusions 8, 9. As the nut 1 is tightened, the ring seals 11, 12 bear against the opposite surfaces of the carrier plate and clamp these in a fluid-tight manner, so that a fluidically tight connection is established between the inner bore 5 and the capillary or capillaries KAP.

FIG. 3A shows a modification of the PCB fitting shown in FIG. 3 for circuit boards for connection of warm and/or cold fluids. Like component parts are provided with like reference signs. Only the differences will be discussed. In contrast to the embodiment according to FIG. 3, the screw 2, which can leave a clearance of approximately 3.2 mm between the two contact faces 7, 10, has a material application R1, which is arranged downstream of the cross bore 6 in the flow direction, and in the axial direction of the connection thread 13 has a recess R2 running around in the peripheral direction, so as to swirl fluid exiting from the cross bore 6 as best as possible. This effect is achieved on account of the peripheral design of the recess R2, regardless of the particular angular position of the cross bore 6.

FIG. 3B shows the PCB fitting in its simplest embodiment as a hollow screw with radial exit, in particular as a convection brake (R1), wherein here a defined tapering of the fluid passage opening of less than 10%, in particular between (0.5 and 4)% is advantageous. A possible additional recess (R5), in particular with the function of a vortex chamber, in particular as a generator, is also advantageous.

FIG. 3C shows the PCB fitting in its simplest embodiment, with the shaping as a vortex tube, by means of a hollow screw with radial exit, in particular as convection brake (R1), wherein a defined tapering of the fluid passage opening of less than 10%, in particular between (0.5 and 4)% is advantageous. A possible additional recess (R5) in particular with the function of a vortex chamber, is also provided, wherein this can also be provided in particular in the form of a recess offset at right angles, wherein the recess in a particular embodiment, in particular can have different recess shapes and/or different diameters, for example can be conical, spherical, and can have complex structures, with the function of swirling the inflowing fluid. In a further particular embodiment, the diameter of the bore can be larger than or the same size as the recess on the opposite side, and vice versa. The advantageous effect is a possible vortex tube effect. In a particular embodiment, the PCB fitting can provide the function of a vortex tube, by extension of the tube (R6) and an adjustment means (R7) for controlling the cold (KA) at the other end of the tube (KA) and/or for controlling the heat (WA) at the other end of the tube (WA). FIG. 3C also shows the PCB fitting in a vortex tube design. The vortex tube generates a differentiated material flow, which separates hot and cold particles of a substance from one another. By defined guidance of the substance flows in accordance with the vortex tube effect, a cold fluid can be provided at one end (KA), and at the other end a hot fluid (WA) with a difference of more than 40 Kelvin. The vortex tube, also referred to as a Ranque-Hilsch vortex tube, is a device without moving parts, with which in particular gaseous fluids can be divided into a hot and a cold flow. Depending on the construction and gas pressure, a temperature difference of more than (20 to 45) Kelvin is produced. A pressurised fluid, in particular gas, is blown tangentially into a vortex chamber, in so doing is set in rotation on account of the geometry of the interior, advantageously at a rate of more than 1,000,000 rpm, and leaves the chamber through an axial air outlet (KA, WA) of different design. Cooled fluid (KA), in particular air, exits by means of a constriction (R1), in particular through the narrow bore, and hot fluid (WA) in particular air, exits through the opposite bore of significantly larger diameter. The temperature difference is dependent on the construction and gas pressure. The geometrical embodiment of the PCB fitting ensures the directed use of the material flow exiting from the vortex tube.

In an embodiment that is not shown, the acoustic sound produced at the tube end (WA), in particular of 3 kHz with a volume of less than 120 dB, can for example be optimised by means of acoustic electrical energy conversion, by means of at least one acoustic sensor, in particular a membrane and/or piezoelement, to a frequency used to pulsate the fluid, and/or used for electrical energy generation by means of at least one acoustic sensor, in particular a piezolelement, disposed in and/or on the connection tube and/or in and/or on the PCB fitting. The arising acoustics occurring during cold/heat generation thus additionally contributes advantageously to the energy supply (energy harvesting). This energy can be fed by means of a control system into the energy generation. It is also advantageous to use the piezoelement as an energy absorber, here for electrical energy generation and/or as an energy transmitter, here for energy delivery and/or conversion of the electrical energy into movement energy at the fluid, thus generating a pulsating fluid. Here, the piezoelements can be in particular piezoelectric actuators, in particular ceramic multi-layer components with precious metal inner electrodes, but also resonantly operated piezoactuators, in particular for generating ultrasound. Here, energy can be obtained, more specifically currents of from 20 μA to 40 mA, with voltage peaks above 15 volts. The piezoelement reacts to pressure by releasing a specific voltage, wherein this piezoeffect can be reversed, i.e. by applying a voltage the shape of such an element changes, i.e., by applying a voltage, the piezoelement disposed for example in and/or on the capillary line and/or in and/or on the PCB fitting deforms. In a particular embodiment, the piezoelement is the surface of the capillary line. This change in shape generates an overpressure, which leads to the extension of the capillary (KA). If the voltage is switched off, the piezoelement and thus the surface of the capillary (KA) reassumes its original shape and the fluid resistance is thus low again and fluid flows on. This has the advantage that the service life of the piezoelements is practically unlimited and there is no mechanical wear, nor any acoustics.

It can be seen in FIG. 3D that the PCT fitting here has a passive function for universal coupling of the vortex tube system and for example a thermal hybrid transmitter system for simultaneous supply with cold and warm fluid by means of the vortex tube and/or another source.

It can be seen in FIG. 3E that the PCT fitting here has a passive and active functionality for universal coupling of the systems with vortex tube functionality and for example a thermal hybrid transmitter system for simultaneously supplying a cold fluid (KA) and warm (WA) fluid, by means of at least one vortex tube.

### DETAILED DESCRIPTION OF THE PREFERRED EMBODIMENTS

A preferred embodiment is one which in which at least one circuit board, through which fluid flows, can be employed and/or used purely as a cooling element in particular for solar modules, in particular for subsequent installation, wherein the circuit board through which fluid flows is equipped internally with capillaries in particular in accordance with the Tichelmann principle, wherein the shapes of the structured capillaries can be freely variable, and in particular including associated fluid connection elements (PCB fittings) for the circuit board for connection in particular of warm and cold fluids and the circuit board through which fluid flows, which is equipped with inlays for assembly of the components and thus ensures at least one functionality, in particular functional optimal heat transfer to the capillary system of the circuit board, and the circuit board through which fluid flows is formed for example purely as a cooling element for solar modules, in particular for subsequent installation and comprising at least one two-component adhesive, in particular having the function of a thermal accumulator, which for example is equipped with nanoparticles, which in particular at least increases a heat transfer and/or mechanical strength and/or improves the electrical property and/or reduces the electrical conductivity between the system components, and in particular consists of a two-component coating material, which comprises: component A: aliphatic isocyanate and/or mixtures thereof; and

component B: binder which can be cross-linked with component A, consisting of: (50 to 98)% binder based on a hydroxyl-group-containing and/or aminofunctional reaction partner and/or mixtures thereof; (0 to 20)% IR-absorbing pigments and/or a comparable material;
and (0 to 5)% nanoparticles, in particular carbon tubes and/or carbon nanohorns and mixtures thereof; and/or (0 to 40)% nanoparticles formed from semi-precious metals and/or ceramic substances having a high thermal conductivity; and/or (0 to 7)% stabilisers; and/or (0 to 3)% auxiliaries.

The PCB fitting, according to the drawing, can be used for circuit boards for the connection of warm and cold fluids and comprises at least one nut (SW17) and a screw (SW 17) with a peripheral radial recess, of a height for example of 3.2 mm, and an O-ring (FPM) on the screw side and an opposite O-ring (FPM) on at least one nut (SW17), with the advantage of a uniform, frictionally engaged pressing against the circuit board (not shown).

Further materials, in particular nanoparticles, can be inter alia also bone ash or spodium. A salt mixture obtained from animal bone comprising the following constituents: calcium phosphate in an amount of (73-84)%, calcium carbonate in an amount of (9.4-10)%, magnesium phosphate in an amount of (2-3)%, and calcium fluids in an amount of less than or equal to 4%, in particular ground to a powder, is used particularly advantageously, in particular with the advantage that bone ash cannot be wetted by liquids, in particular liquid metals.

### LIST OF REFERENCE SIGNS, ABBREVIATIONS

BA base element, PCB, carrier material, circuit board, static material for receiving modules
CAD computer-aided design
CNF carbon nanofibres
CNH carbon nanohorn, single-walled carbon nanohorn (SWNH)
CNT carbon nanotubes
DR fluid, for example, compressed air, compressed fluid, compressed pressurised air
EMC electromagnetic compatibility
FPM O-ring
FU filler material, for example plastics material, ceramic, cavity with vacuum, insulator
KA cold in Kelvin, degrees Celsius for example for fluid
KA in FIG. 3D line for cold fluid
KAP capillary, line for example for fluid
KL adhesive layer with different thickness, thermal accumulator, adhesive
PCB printed circuit board, PC board, board, circuit board, printed board, printed circuit, carrier material
PE thermoelectric generator, Peltier element, Seebeck element, PE module
PTFE polyimide, Teflon
PV photovoltaic cell, PV solar cells, PV module
R radius of curvature of the PCB fitting, here with the diameter 3 of mean height 4.6
R1 bore, area, material, for example for convection brake, tapering of the diameter
R2 recess with a depth, shape, geometry
R4, R5 recess with a depth, shape, geometry
R6 vortex tube, for example vortex tube chamber, warm side (WA)
R7 control valve, for example vortex tube
SW17 nut, screw
S insulating web
SO sun, radiation heat, IR radiation
TPV thermophotovoltaic system
OB surface, visible face
WA heat in Kelvin, degrees Celsius for example for fluid
WA in FIG. 3D conduction of warm fluid
1 nut
2 screw
3 threaded shank
4 internal thread
5 inner bore
6 cross bore
7 lower contact face
8 protrusion
9 further protrusion
10 upper stop face
11 ring seal
12 ring seal
13 connection thread

1.-14. (canceled)

15. A device for generating electrical energy comprising:
a photovoltaic cell connected heat-conductively to a carrier plate through which fluid can flow.

16. The device according to claim 15, wherein the carrier plate through which fluid can flow comprises at least one thermoelectric generator, which is thermally coupled to a flow channel of the carrier plate.

17. The device according to claim 16, wherein the carrier plate through which fluid can flow comprises a circuit board, wherein electrical conductor tracks of the circuit board are electrically connected to the at least one thermoelectric generator.

18. The device according to claim 15, wherein the photovoltaic cell is provided as part of a unitary circuit board, and at least one flow channel is formed in the unitary circuit board.

19. The device according to claim 15, wherein a plurality of flow channels are formed in the carrier plate and are provided in accordance with a Tichelmann principle with a constant fluid resistance, wherein an intake line, a feed line, or both and a return line, a discharge, or both include a channel geometry, a channel cavity, a length of a flow channel, a shape of a passage opening of the flow channel, an inner surface structure of the flow channel, or any combination thereof formed in a tailored manner.

20. The device according to claim 16, comprising a thermally conductive inlay embedded in the carrier plate, wherein the thermally conductive inlay extends between the thermoelectric generator and the flow channel or between the thermoelectric generator and the photovoltaic cell.

21. The device according to claim 15, wherein the carrier plate comprises a flow channel that is configured to connect to a connection line using a line connection via a printed circuit board (PCB) fitting connected sealingly to the carrier plate.

22. The device according to claim 15, wherein the carrier plate comprises a flow channel, and a nanoparticle-containing fluid is received in the flow channel.

23. The device according to claim 15, comprising a frequency control system configured to introduce the fluid into the carrier plate in a frequency-controlled manner.

24. The device according to claim 15, comprising a vortex tube connected to the carrier plate.

25. The device according to claim 16, comprising at least one adhesively bonded connection between the carrier plate and the thermoelectric generator, between the thermoelectric generator and the photovoltaic cell, between the carrier plate and photovoltaic cell, or any combination thereof.

26. The device according to claim 25, wherein the adhesively bonded connection contains nanoparticles.

27. The device according to claim 25, wherein the adhesively bonded connection is produced from an adhesive consisting of:
component A comprising aliphatic isocyanate, mixtures including aliphatic isocyanate, or any combinations thereof; and
component B comprising a binder configured to be cross-linked with component A, the component B consisting in weight % of:
50 to 98% binder based on a hydroxyl-group-containing aminofunctional reaction partner, an aminofunctional reaction partner, or any combinations thereof;
0 to 20% IR-absorbing pigments, a comparable substance, or any combination thereof;
0 to 40% carbon nanotubes, carbon nanofibers, carbon nanohorns, or any combination thereof;
0 to 40% nanoparticles formed from semi-precious metals, ceramic substances with high thermal conductivity, or any combination thereof;
0 to 7% stabilizers; and
0 to 3% auxiliaries.

28. The device according to claim 27, wherein a layer thickness of an adhesive layer forming the adhesively bonded connection is 10 μm to 70 μm.
